(19) United States
(12) Patent Application Publication
(10) Pub. No.: US 2005/0067635 A1
(43) Pub. Date: Mar. 31, 2005

(54) Method of manufacturing electronic component, method of manufacturing electro-optical device, electronic component, and electro-optical device

(75) Inventor: Atsushi Saito, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/916,609

(22) Filed: Aug. 12, 2004

(30) Foreign Application Priority Data
Aug. 21, 2003 (JP) 2003-297651
Mar. 11, 2004 (JP) 2004-069556

(51) Int. Cl. H01L 23/48

(52) U.S. Cl. 257/222

(57) ABSTRACT

A method of manufacturing an electronic component, including: forming a thermoplastic resin layer on a surface of a semiconductor substrate including a plurality of integrated circuits and a bump electrode provided on each of the integrated circuits, to bury the bump electrode; forming a conductive pattern on a surface of the thermoplastic resin layer opposite to the semiconductor substrate, and electrically connecting the conductive pattern to the bump electrode; and dividing the semiconductor substrate in units of the integrated circuits.

Japanese Patent Application No. 2003-297651, filed on Aug. 21, 2003, and Japanese Patent Application No. 2004-69556, filed on Mar. 11, 2004, are hereby incorporated by reference in their entirety.

### BACKGROUND OF THE INVENTION

The present invention relates to a method of manufacturing an electronic component, a method of manufacturing an electro-optical device, an electronic component, and an electro-optical device.

In various types of electronic instruments, an electronic component such as a semiconductor IC is generally mounted on a circuit board or the like to make up a part of an electronic circuit. As a method for mounting an electronic component on a circuit board or the like, various methods have been proposed. For example, a mounting method in which bump electrodes of an electronic component are bonded to conductive pads on a circuit board and the space between the electronic component and the circuit board is filled and sealed with an underfill resin has been known as the most general method.

As a mounting method widely used for a liquid crystal display device or the like, a method of mounting an electronic component through an anisotropic conductive film (ACF) has been known. In this method, an electronic component is pressed against a circuit board or a glass substrate, which makes up a liquid crystal panel, through an ACF in which conductive fine particles are dispersed in a thermosetting resin while heating the electronic component using a pressure heating head. This causes bump electrodes of the electronic component to be electrically connected with terminals on the substrate through the conductive particles, and the conductive connection state is maintained by allowing the thermosetting resin to be cured in this state.

A method of forming an electronic component has been known in which a circuit board in which conductive pads are formed on one surface of a substrate formed of a thermoplastic resin is provided, and an IC chip provided with bump electrodes is pressed against the surface of the circuit board opposite to the conductive pad formation surface under heating, whereby the bump electrodes are inserted into the thermoplastic resin of the circuit board and secured in a state in which the ends of the bump electrodes are electrically connected with the conductive pads from the inside of the circuit board (see Japanese Patent Application Laid-open No. 2003-124259, for example).

However, in the method of filling the space between the electronic component and the circuit board with the underfill resin, it may take time to inject the underfill resin.

In the mounting method using the ACF, since the conductive particles must be reduced in size as the pitch between the terminals is reduced, the cost of the ACF may be increased.

The method disclosed in Japanese Patent Application Laid-open No. 2003-124259 may make it difficult to align the bump electrodes of the IC chip and the conductive pads of the circuit board.

### BRIEF SUMMARY OF THE INVENTION

According to a first aspect of the present invention, there is provided a method of manufacturing an electronic component, comprising:
forming a thermoplastic resin layer on a surface of a semiconductor substrate including a plurality of integrated circuits and a bump electrode provided on each of the integrated circuits, to bury the bump electrode;
forming a conductive pattern on a surface of the thermoplastic resin layer opposite to the semiconductor substrate, and electrically connecting the conductive pattern to the bump electrode; and
dividing the semiconductor substrate in units of the integrated circuits.

According to a second aspect of the present invention, there is provided a method of manufacturing an electro-optical device, comprising:
mounting an electronic component manufactured by the above-described method on a circuit board by thermocompression bonding; and
mounting the circuit board on an electro-optical panel.

According to a third aspect of the present invention, there is provided a method of manufacturing an electro-optical device, comprising:
mounting an electronic component manufactured by the above-described method on a substrate of an electro-optical panel by thermocompression bonding.

According to a fourth aspect of the present invention, there is provided an electronic component comprising:
a semiconductor substrate including a bump electrode;
a thermoplastic resin layer formed on a surface of the semiconductor substrate on which the bump electrode is formed; and
a conductive pattern formed on a surface of the thermoplastic resin layer and electrically connected to the bump electrode,
wherein an outer edge of the thermoplastic resin layer is disposed on or inside an outer edge of the semiconductor substrate.

According to a fifth aspect of the present invention, there is provided an electro-optical device comprising:
an electro-optical panel; and
a circuit board mounted on the electro-optical panel,
wherein the above-described electronic component is mounted on the circuit board.

According to a sixth aspect of the present invention, there is provided an electro-optical device comprising:
an electro-optical panel; and
the above-described electronic component mounted on a substrate of the electro-optical panel.

According to a seventh aspect of the present invention, there is provided an electro-optical device comprising:
any of the above-described electro-optical devices; and
control means for the electro-optical device.

### BRIEF DESCRIPTION OF THE SEVERAL VIEWS OF THE DRAWING

FIGS. 1A to 1C are diagrams for illustrating a method of manufacturing an electronic component according to a first embodiment of the present invention.

FIGS. 2A to 2C are diagrams for illustrating a method of manufacturing an electronic component according to a second embodiment of the present invention.

FIGS. 3A to 3D are diagrams for illustrating a method of manufacturing an electronic component according to a modification of the second embodiment of the present invention.

FIGS. 4A to 4C are diagrams for illustrating a method of manufacturing an electronic component according to a third embodiment of the present invention.

FIGS. 5A to 5D are diagrams for illustrating a method of manufacturing an electronic component according to a fourth embodiment of the present invention.

FIG. 6 is a diagram for illustrating a method of manufacturing an electronic component according to the second embodiment of the present invention.

FIG. 7 is a diagram for illustrating a method of manufacturing an electronic component according to the fourth embodiment of the present invention.

FIG. 8 is a diagram for illustrating a structure of an electro-optical device according to a fifth embodiment of the present invention.

FIG. 9 is a diagram for illustrating a structure of an electro-optical device according to a sixth embodiment of the present invention.

FIG. 10 is a diagram showing a display control system of an electronic instrument including an electro-optical device according to one embodiment of the present invention.

FIG. 11 is a diagram showing an electronic instrument.

### DETAILED DESCRIPTION OF THE EMBODIMENTS

The present invention may provide a method of easily, inexpensively, and efficiently manufacturing an electronic component with the improved electrical reliability.

(1) According to one embodiment of the present invention, there is provided a method of manufacturing an electronic component, comprising:
forming a thermoplastic resin layer on a surface of a semiconductor substrate including a plurality of integrated circuits and a bump electrode provided on each of the integrated circuits, to bury the bump electrode;
forming a conductive pattern on a surface of the thermoplastic resin layer opposite to the semiconductor substrate, and electrically connecting the conductive pattern to the bump electrode; and
dividing the semiconductor substrate in units of the integrated circuits.

In this method, the thermoplastic resin layer is formed on the surface of the semiconductor substrate so that the bump electrode is buried; the conductive pattern electrically connected to the bump electrode is formed on the surface of the thermoplastic resin layer opposite to the semiconductor substrate; and the semiconductor substrate is divided in units of the integrated circuits. Therefore, since the thermoplastic resin and the conductive patterns can be formed collectively while the integrated circuits are integrally formed on the semiconductor substrate, the electronic component can be efficiently manufactured, whereby the manufacturing cost can be reduced. Moreover, since the conductive pattern can be formed on the basis of the single semiconductor substrate which shows a dimensional change due to a temperature change smaller than that of the thermoplastic resin, alignment can be facilitated and the positional accuracy of the conductive pattern can be improved, whereby electrical reliability can be secured. As the semiconductor substrate in this embodiment, a semiconductor wafer before being divided into semiconductor IC chips, a ceramic substrate before being divided into semiconductive ceramic capacitor, and the like can be given. The thermoplastic resin layer in this embodiment may be integrally formed on the semiconductor substrate, or may be formed in a state of divided pieces. In the latter case, the thermoplastic resin layer may be formed in a state in which the thermoplastic resin layer is divided in units of the integrated circuits.

(2) In this method of manufacturing an electronic component, the thermoplastic resin layer may be formed while heating the semiconductor substrate or the thermoplastic resin layer.

If at least part of the thermoplastic resin in contact with the bump electrode can be soften or melt by heating the semiconductor substrate or the thermoplastic resin layer, the bump electrode can be easily and securely buried in the thermoplastic resin.

(3) In this method of manufacturing an electronic component, the thermoplastic resin layer may be formed on the semiconductor substrate by molding.

If the thermoplastic resin layer is formed by molding, the shape of the thermoplastic resin layer can be defined with high accuracy. For example, this enables part of the bump electrode to be exposed from the surface of the thermoplastic resin layer opposite to the semiconductor substrate.

(4) In this method of manufacturing an electronic component, the thermoplastic resin layer may be formed so that part of the bump electrode is exposed from the surface of the thermoplastic resin layer.

Since part of the bump electrode is exposed from the surface of the thermoplastic resin, alignment of the conductive pattern can be facilitated and the conductive pattern can be electrically connected to the bump electrodes with ease and reliability.

(5) In this method of manufacturing an electronic component, the thermoplastic resin layer may be formed so that the bump electrode is electrically connected to conductive material previously disposed on the side opposite to the semiconductor substrate; and the conductive pattern may be formed by patterning the conductor material.

By previously providing conductive material over the entire surface of the thermoplastic resin layer or in a range larger than the bump electrode, the bump electrode can be securely caused to be electrically connected to the conductive material. The conductive material can be patterned into a conductive pattern having a desired shape or pattern in the step of forming the conductive pattern. Therefore, alignment in the step of forming the thermoplastic resin layer can be made easier than the case of forming a conductive pattern on the surface of the thermoplastic resin layer.

(6) The method of manufacturing an electronic component may further comprise: forming a hole to expose part of the bump electrode on a surface of the thermoplastic resin layer opposite to the semiconductor substrate and filling the hole with conductive material, between the steps of forming the thermoplastic resin layer and the conductive pattern.

By filling the holes with the conductive material, the bump electrode and the conductive pattern can be electrically connected more securely. Therefore, electrical reliability can be improved.

(7) In this method of manufacturing an electronic component, the conductive pattern may be formed by applying a fluid material on a surface of the thermoplastic resin layer opposite to the semiconductor substrate and curing the fluid material.

This enables alignment to be facilitated, whereby the conductive pattern can be accurately provided. The fluid material may be cured by drying using heat, irradiation, drying, baking or chemical reaction, depending on the characteristics of the fluid material.

(8) In this method of manufacturing an electronic component, the fluid material may be applied by ejecting the fluid material in the form of drops.

This makes the application position and the application amount of the fluid material more accurate. The drops may be ejected by using a piezoelectric type or thermal-bubble type of ink-jet head, for example.

(9) In this method of manufacturing an electronic component, the fluid material may be applied by printing the fluid material in the form of paste.

This enables to efficiently form the conductive pattern with reduced cost.

(10) In this method of manufacturing an electronic component, the step of forming the conductive pattern may include forming a resist layer having a patterned opening on a surface of the thermoplastic resin layer opposite to the semiconductor substrate; and the conductive pattern may be formed in the opening in the resist layer.

This enables to form the conductive pattern conforming to the design.

(11) In this method of manufacturing an electronic component, the step of forming the conductive pattern may include a step of ejecting a solvent containing conductive fine particles; and the resist layer may be formed so that an upper surface of the resist layer has a lower affinity to the solvent in comparison with the surface of the thermoplastic resin layer opposite to the semiconductor substrate.

This enables to form the conductive pattern efficiently.

(12) This method of manufacturing an electronic component may further comprise: removing the resist layer after the step of forming the conductive pattern.

This enables to manufacture a highly reliable electronic component.

(13) According to one embodiment of the present invention, there is provided a method of manufacturing an electro-optical device, comprising:
mounting an electronic component manufactured by the above-described method on a circuit board by thermocompression bonding; and
mounting the circuit board on an electro-optical panel.

In the method of manufacturing an electro-optical device according to this embodiment, since the electronic component is mounted by the thermocompression bonding, the thermoplastic resin is soften or melt. Therefore, the electronic components can be easily mounted on the circuit board. In particular, if resin exposed from the surface of the circuit board is a thermoplastic resin, the resin of the circuit board and the thermoplastic resin layer of the electronic components easily melt and adhere, whereby the electronic components can be extremely easily mounted.

(14) According to one embodiment of the present invention, there is provided a method of manufacturing an electro-optical device, comprising:
mounting an electronic component manufactured by the above-described method on a substrate of an electro-optical panel by thermocompression bonding.

In the method of manufacturing an electro-optical device according to this embodiment, since the electronic component is mounted by the thermocompression bonding, the thermoplastic resin is soften or melt. Therefore, the electronic components can be easily mounted on the electro-optical panel. As a material for the substrate which makes up the electro-optical panel, glass, quartz, plastic, ceramic, and the like can be given. The electronic component can be easily mounted regardless of which of these materials is used.

(15) According to one embodiment of the present invention, there is provided an electronic component comprising:
a semiconductor substrate including a bump electrode;
a thermoplastic resin layer formed on a surface of the semiconductor substrate on which the bump electrode is formed; and
a conductive pattern formed on a surface of the thermoplastic resin layer and electrically connected to the bump electrode,
wherein an outer edge of the thermoplastic resin layer is disposed on or inside an outer edge of the semiconductor substrate.

This enables provision of a electronic component which can be easily mounted on a circuitboard.

(16) According to one embodiment of the present invention, there is provided an electro-optical device comprising:
an electro-optical panel; and
a circuit board mounted on the electro-optical panel,
wherein the above-described electronic component is mounted on the circuit board.

Since the electronic component can be easily and securely mounted on the circuit board, a highly reliable electro-optical device can be provided.

(17) According to one embodiment of the present invention, there is provided an electro-optical device comprising:
an electro-optical panel; and
the above-described electronic component mounted on a substrate of the electro-optical panel.

Since the electronic component can be easily and securely mounted on the substrate which makes up the electro-optical panel, a highly reliable electro-optical device can be provided.

(18) According to one embodiment of the present invention, there is provided an electro-optical device comprising:
any of the above-described electro-optical devices; and
control means for the electro-optical device.

These embodiments of the present invention will be described in detail below with reference to the drawings. Note that the drawings to be referred to in the following description show the configuration of the embodiments schematically, and do not represent the actual shape or dimensional ratio.

First Embodiment

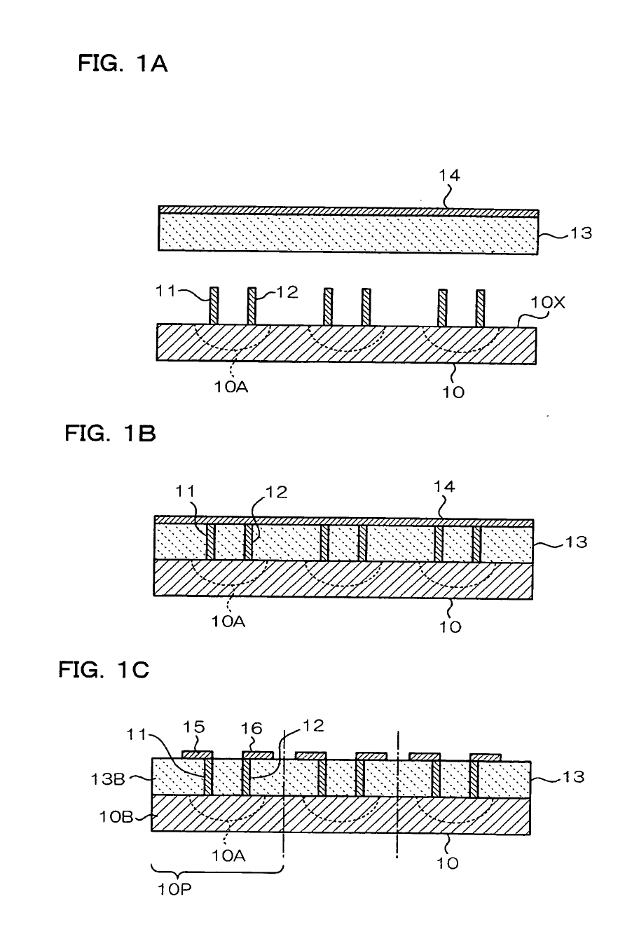

The first embodiment according to the present invention is described below with reference to FIGS. 1A to 1C. In this embodiment, as shown in FIG. 1A, a semiconductor substrate 10 integrally provided with a plurality of integrated circuits 10A is provided. The semiconductor substrate 10 may be a semiconductor substrate which is formed of a silicon single crystal, a compound semiconductor single crystal, or the like and includes a predetermined electronic circuit structure as the integrated circuit 10A. However, the semiconductor substrate 10 may be a ceramic substrate. The semiconductor substrate 10 is formed to a thickness of about 100 to 800 μm when the semiconductor substrate 10 is a semiconductor wafer, and is formed to a thickness of about 1 to 5 mm when the semiconductor substrate 10 is a ceramic stack.

In either case, the integrated circuits 10A are integrally formed in the semiconductor substrate 10. The integrated circuits 10A are arranged along a mounting surface 10X on one surface of the semiconductor substrate 10. The arrangement configuration may be a one-dimensional arrangement configuration (columns), or may be a two-dimensional (planar) arrangement configuration.

Bump electrodes (projection electrodes) 11 and 12 are formed on the mounting surface 10X of the semiconductor substrate 10 in units of the integrated circuits 10A. The number of bump electrodes 11 and 12 is arbitrary, and may be one or three or more. In the example shown in FIG. 1, two bump electrodes are formed in units of the integrated circuits 10A. It suffices that the bump electrodes 11 and 12 be formed of conductive material. For example, the bump electrodes 11 and 12 are formed of a metal such as Cu, Ni, Au, Ag, or Al. As the structure of the bump electrode, the surface of a projecting section of a metal layer formed of Cu, Ni, Al, or the like may be covered with a thin film formed of Au, Ag, Sn, or the like. The bump electrodes 11 and 12 have a diameter of about 10 to 30 μm and are formed at a pitch of about 30 to 50 μm, for example. The projection height of the bump electrodes 11 and 12 is about 10 to 50 μm. The projection height is set at a value almost the same as the thickness of a thermoplastic resin layer described later.

A thermoplastic resin layer 13 is formed on the mounting surface 10X of the semiconductor substrate 10 configured as described above. The thermoplastic resin layer 13 is formed of a thermoplastic resin such as a polyester resin, polyamide resin, aromatic polyester resin, aromatic polyamide resin, tetrafluoroethylene resin, or polyimide resin. In this embodiment, the thermoplastic resin layer 13 is formed to a thickness of 20 to 50 μm, and typically about 30 μm. The thermoplastic resin layer 13 may have a thickness the same as the projection height of the bump electrodes 11 and 12, or may have a thickness about 1 to 10 μm greater than the projection height of the bump electrodes 11 and 12. A conductive layer 14 formed of a metal such as Cu, Al, or Au or other conductive material is formed on one surface of the thermoplastic resin layer 13. The conductive layer 14 may be merely placed on the surface of the thermoplastic resin layer 13, or may be bonded (adhering) to the surface of the thermoplastic resin layer 13. The conductive layer 14 is formed to a thickness of 1 to 20 μm, and typically about 10 μm, for example.

The thermoplastic resin layer 13 is mechanically formed on the mounting surface 10X of the semiconductor substrate 10. For example, the thermoplastic resin layer 13 is formed on the mounting surface 10X of the semiconductor substrate 10 while pressing the thermoplastic resin layer 13 and the conductive layer 14 against the mounting surface 10X. The thermoplastic resin layer 13 may be formed while heating the semiconductor substrate 10 or the thermoplastic resin layer 13. For example, the semiconductor substrate 10 is heated by causing a heating head or a heating stage to come in contact with the surface of the semiconductor substrate 10 opposite to the mounting surface 10X, or the thermoplastic resin layer 13 is heated by causing a heating head or a heating stage to come in contact with the conductive layer 14. The thermoplastic resin layer 13 and the conductive layer 14 may be pressed against the semiconductor substrate 10 using a roller or the like. In this case, the thermoplastic resin layer 13 may be heated by using the roller. The heating temperature is set to be equal to or higher than the softening temperature of the thermoplastic resin layer 13, but less than the melting temperature of the bump electrodes 11 and 12 or the heat-resistant temperature of the semiconductor substrate 10. The heating temperature may be usually in the range of 120 to 350° C.

When the thermoplastic resin layer 13 is formed on the semiconductor substrate 10 as described above, the bump electrodes 11 and 12 are inserted into the thermoplastic resin layer 13. The bump electrodes 11 and 12 are buried in the thermoplastic resin layer 13 when the semiconductor substrate 10 adheres to the thermoplastic resin layer 13. As shown in FIG. 1B, the bump electrodes 11 and 12 are electrically connected to the conductive layer 14 when the step of forming the thermoplastic resin layer is completed. This connection state is implemented by applying a stress equal to or greater than the stress necessary for the bump electrodes 11 and 12 to push through the thermoplastic resin layer 13 which has been softened or melted by heating between the semiconductor substrate 10 and the conductive layer 14. The bump electrodes 11 and 12 and the conductive layer 14 may be alloyed by heating. In this case, the heating temperature differs depending on the materials for the bump electrodes 11 and 12 and the conductive layer 14, and may be about 200 to 400° C.

As shown in FIG. 1C, conductive patterns 15 and 16 electrically connected to the bump electrodes 11 and 12 are formed by patterning the conductive layer 14. As the patterning method, a method in which a mask is formed by a conventional photolithographic method or the like using a resist or the like, and the conductive layer 14 is etched using the mask can be given. The conductive patterns 15 and 16 may be terminals such as conductive pads, or may be an interconnect pattern formed in a predetermined pattern.

The semiconductor substrate 10 and the thermoplastic resin layer 13 are divided in units of the integrated circuits 10A as indicated by one-dot lines shown in FIG. 1C to form a plurality of electronic components 10P (part dividing step). As the dividing method in this step, a dicing method, a scribe and break method, or the like may be used. The electronic component 10P includes an electronic structure split substrate 10B including the integrated circuit 10A, a thermoplastic resin split layer 13B, and the conductive patterns 15 and 16 electrically connected to the bump electrodes 11 and 12. The electronic component 10P can be easily mounted by using a method in which the electronic structure split substrate 10B is pressed against a mounting target such as a circuit board while heating the electronic structure split substrate 10B using a pressure heating head (not shown), thereby causing the thermoplastic resin split layer 13B to soften or melt to adhere to the mounting target.

In this embodiment, since the thermoplastic resin layer 13 and the conductive patterns 15 and 16 can be formed collectively on the semiconductor substrate 10 in which the integrated circuits 10A are integrally formed, the electronic components can be efficiently manufactured, whereby the manufacturing cost can be reduced. Moreover, since the semiconductor substrate 10 is formed by a silicon substrate or a ceramic substrate, the semiconductor substrate 10 shows a dimensional change due to a temperature change significantly smaller than that of the thermoplastic resin. Therefore, since the conductive patterns 15 and 16 can be formed collectively in areas in which the electronic components are formed based on the semiconductor substrate 10 which shows only a small amount of dimensional change, alignment can be facilitated and positional accuracy of the conductive patterns 15 and 16 in relation to the bump electrodes 11 and 12 can be increased, whereby sufficient electrical reliability can be secured.

In this embodiment, since the conductive layer 14 is formed in advance on one surface of the thermoplastic resin layer 13, and the bump electrodes 11 and 12 are caused to be electrically connected to the conductive layer 14 from the inside of the thermoplastic resin layer 13 when forming the thermoplastic resin layer 13 on the semiconductor substrate 10, the bump electrodes 11 and 12 can be securely caused to be electrically connected to the conductive layer 14 without alignment or the like. In this case, the conductive layer 14 may be entirely formed on one surface of the thermoplastic resin layer 13. However, the conductive layer 14 is not necessarily formed on the entire surface. For example, the conductive layer 14 may be formed in the shape of an island so as to spread around the formation regions of the bump electrodes 11 and 12 to a certain extent, or may be formed in the shape of an island corresponding to the integrated circuits 10A. In either case, the conductive layer 14 can be reliably caused to be electrically connected to the bump electrodes 11 and 12 by forming the conductive layer 14 so as to include a region in which the conductive layer 14 overlaps the bump electrodes 11 and 12 and to cover a wide range around the overlapping region.

Second Embodiment

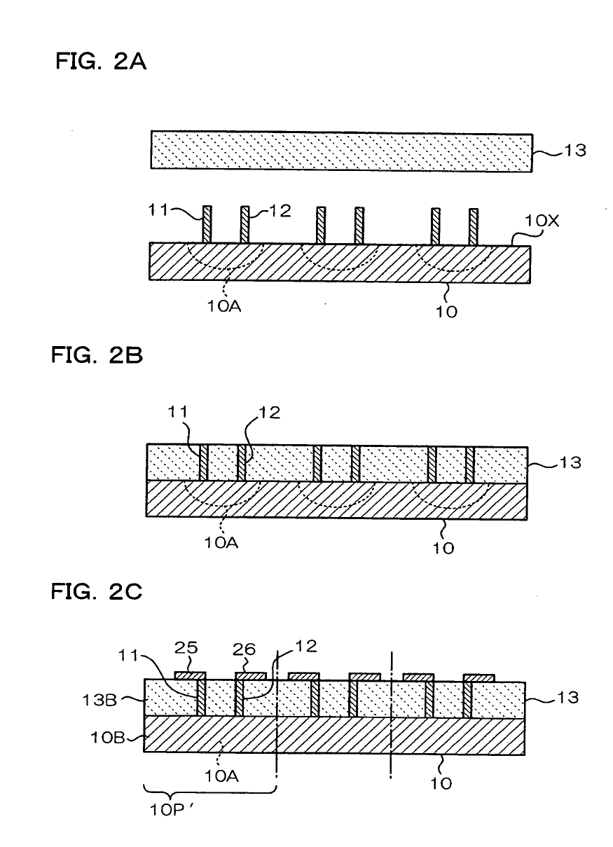

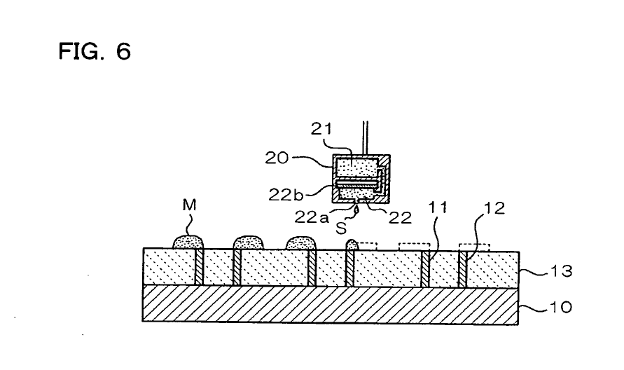

The second embodiment according to the present invention is described below with reference to FIGS. 2A to 2C and FIG. 6. In this embodiment, constituent elements the same as the constituent elements in the first embodiment are denoted by the same symbols. Description of these constituent elements is omitted. In this embodiment, as shown in FIG. 2A, the thermoplastic resin layer 13 is formed on the semiconductor substrate 10 by using the same method as in the first embodiment. However, in this embodiment, a conductor layer is not formed on the surface of the thermoplastic resin layer 13. As shown in FIG. 2B, in the step of forming the thermoplastic resin layer, the ends of the bump electrodes 11 and 12 are exposed from the surface of the thermoplastic resin layer 13 opposite to the semiconductor substrate 10.

As shown in FIG. 2C, conductors 25 and 26 are formed on the surface of the thermoplastic resin layer 13 so that the conductors 25 and 26 are electrically connected to the partially exposed bump electrodes 11 and 12. The conductors 25 and 26 may be formed by using the same method as in the first embodiment. In this embodiment, the conductors 25 and 26 are formed by applying a fluid material to the surface of the thermoplastic resin layer 13 and curing the applied fluid material. According to this embodiment, a liquid material is applied by discharging a droplet S onto the surface of the thermoplastic resin layer 13 from a discharge head 20 shown in FIG. 6.

The discharge head 20 has essentially the same structure as that used for an ink-jet printer. In more detail, a container chamber 21 which contains a liquid material and a discharge chamber 22 which communicates with the container chamber 21 are provided inside the discharge head 20. A liquid material supply line is connected with the container chamber 21. A piezoelectric inner wall section 22b formed of an operable piezoelectric is provided so as to face the discharge chamber 22, and a discharge port 22a which communicates with the outside is formed. The piezoelectric inner wall section 22b is formed so as to be deformed corresponding to a drive voltage. The liquid material flows into the discharge chamber 22 from the container chamber 21 when the piezoelectric inner wall section 22b is bent outward and the capacity of the discharge chamber 22 is increased, and the droplet S of the liquid material is discharged from the discharge port 22a when the piezoelectric inner wall section 22b is bent inward and the capacity of the discharge chamber 22 is decreased.

The liquid material is a material in which conductive particles are dispersed in a solvent, for example. The application amount can be precisely set by the number of discharges of the droplets S. The thermoplastic resin layer 13 and the discharge head 20 can be relatively moved so that the impact position of the droplet S discharged from the discharge head 20 can be controlled. Therefore, a liquid material M can be applied to the surface of the thermoplastic resin layer 13 at an arbitrary position in an arbitrary shape by adjusting the number of discharges and the impact position of the droplets S. The liquid material M is cured by drying or sintering to form the conductors 25 and 26 shown in FIG. 2C.

In the above-described step of forming the conductors, the conductors 25 and 26 can be precisely formed without patterning. Moreover, this method has an advantage in that the alignment operation can be facilitated since the conductors 25 and 26 can be formed using the partially exposed bump electrodes 11 and 12 as targets.

In this step, a conductive paste may be used as the fluid material. The conductive paste may be printed on the surface of the thermoplastic resin layer 13 by using a printing method (screen printing method, for example), and the conductive paste may be cured by heating or allowing the conductive paste to stand in this state. This method enables the conductors 25 and 26 to be inexpensively and efficiently formed by using the printing method.

An electronic component 10P′ formed by this embodiment has essentially the same structure and effect as those of the electronic component 10P in the first embodiment.

In the conductor formation step, the fluid material is selectively applied to the surface of the thermoplastic resin layer 13. As the fluid material, powder or the like may be used instead of the liquid material or paste material. As the curing method for the fluid material, various methods such as a drying treatment which volatilizes a solvent, a sintering treatment which causes a welding or sintering effect to occur by heating, or a treatment which causes curing by a chemical reaction may be applied corresponding to the material characteristics.

Modification

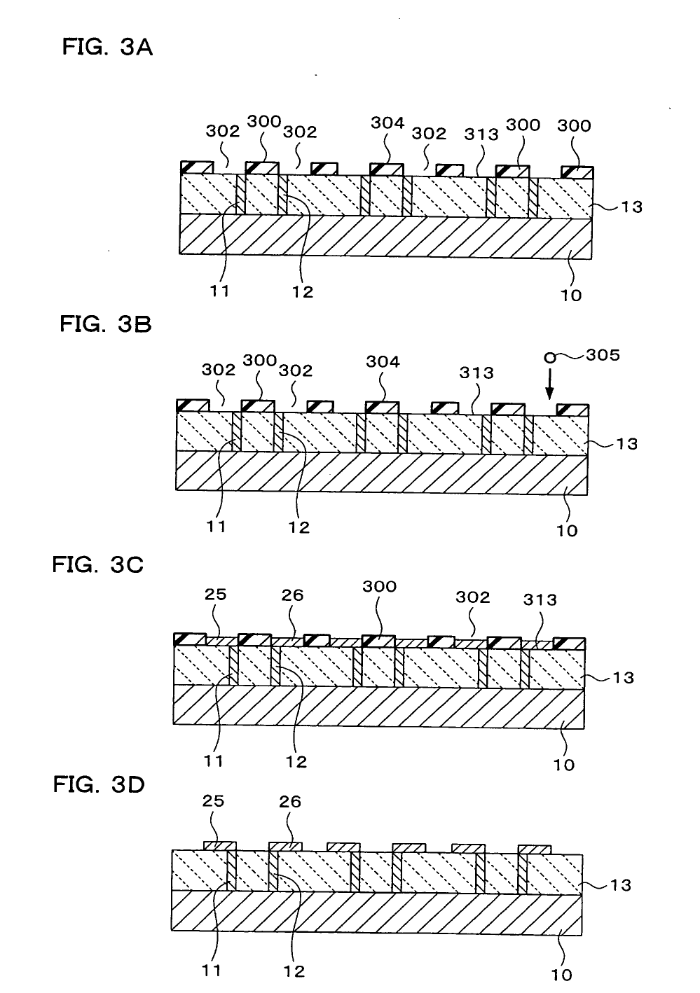

A modification of the second embodiment is described below with reference to the drawings. FIGS. 3A to 3D are views illustrating a method of manufacturing an electronic component according to this modification. In this modification, as shown in FIG. 3A, the step of forming the conductors 25 and 26 includes a step of forming a resist layer 300 having patterned openings 302 on the surface of the thermoplastic resin layer 13 opposite to the semiconductor substrate 10. The step of forming the resist layer 300 is not particularly limited. The resist layer 300 may be formed by using a conventional method. For example, a resist layer may be formed on the entire surface of the thermosetting resin layer 13, and the resist layer 300 having the openings 302 may be formed by removing a part of the resist layer. In this case, a part of the resist layer may be removed by an exposure step and a development step, for example. The opening 302 may be formed in the shape of a groove. In this modification, the conductors 25 and 26 are formed on sections 313 of the thermosetting resin layer 13 exposed in the openings 302 (see FIG. 3C). In other words, the conductors 25 and 26 may be formed in the openings 302. This enables the conductors 25 and 26 to be formed to have a width the same as the width of the openings 302. Specifically, the width of the conductors 25 and 26 can be limited by the openings 302. Therefore, the conductors 25 and 26 can be formed conforming to the design.

In this modification, the conductors 25 and 26 may be formed by using a solvent 305 containing conductive fine particles, as shown in FIG. 3B. In more detail, the conductors 25 and 26 may be formed by selectively discharging the solvent 305 containing conductive fine particles. This enables the conductors 25 and 26 to be efficiently formed. As shown in FIG. 3B, the solvent 305 may be discharged from above the opening 302. In other words, the solvent 305 may be discharged onto the exposed section 313. This enables the conductors 25 and 26 to be formed on the exposed sections 313. The conductive fine particles may be formed of a material which is rarely oxidized and has low electrical resistance, such as gold or silver. “Perfect Gold” manufactured by Vacuum Metallurgical Co., Ltd. may be used as a solvent containing gold fine particles, and “Perfect Silver” manufactured by Vacuum Metallurgical Co., Ltd. may be used as a solvent containing silver fine particles. There are no specific limitations to the size of the fine particles. The fine particles used herein refer to particles which can be discharged together with a dispersion medium. The conductive fine particles may be covered with a coating material in order to prevent occurrence of a reaction. The solvent 305 may be dried to only a small extent and have resolubility. The conductive fine particles may be uniformly dispersed in the solvent 305. The step of forming the conductors 25 and 26 may include discharging the solvent 305. The solvent 305 containing conductive fine particles may be discharged by using an ink-jet method, a Bubble Jet (registered trademark) method, or the like. The solvent 305 may be discharged by mask printing or screen printing, or by using a dispenser. A conductive member may be formed by performing a step of volatilizing the dispersion medium, a step of decomposing the coating material which protects the conductive fine particles, and the like. The conductors 25 and 26 may be formed as shown in FIG. 3C by performing these steps or by repeating these steps.

In this modification, the resist layer 300 may be formed so that an upper surface 304 of the resist layer 300 has an affinity to the solvent 305 lower than that of the surface of the thermoplastic resin layer 13 opposite to the semiconductor substrate 10. In other words, the resist layer 300 may be formed so that the upper surface 304 has an affinity to the solvent 305 lower than that of the exposed section 313. Since this allows the solvent 305 to easily enter the opening 302 in the resist layer 300, the conductors 25 and 26 can be efficiently manufactured even if the width of the opening 302 is smaller than the diameter of the droplet of the solvent 305. Specifically, a conductor having a width smaller than the diameter of the droplet of the solvent 305 can be efficiently manufactured. For example, the resist layer 300 may be formed by utilizing a material having an affinity to the solvent 305 lower than that of the resin which makes up the thermoplastic resin layer 13.

In this modification, the manufacturing method may include a step of removing the resist layer 300 after forming the conductors 25 and 26, as shown in FIG. 3D. Since the conductive fine particles on the resist layer 300 can be removed by removing the resist layer 300, a highly reliable electronic component in which the conductors 25 and 26 are rarely short-circuited can be formed.

Third Embodiment

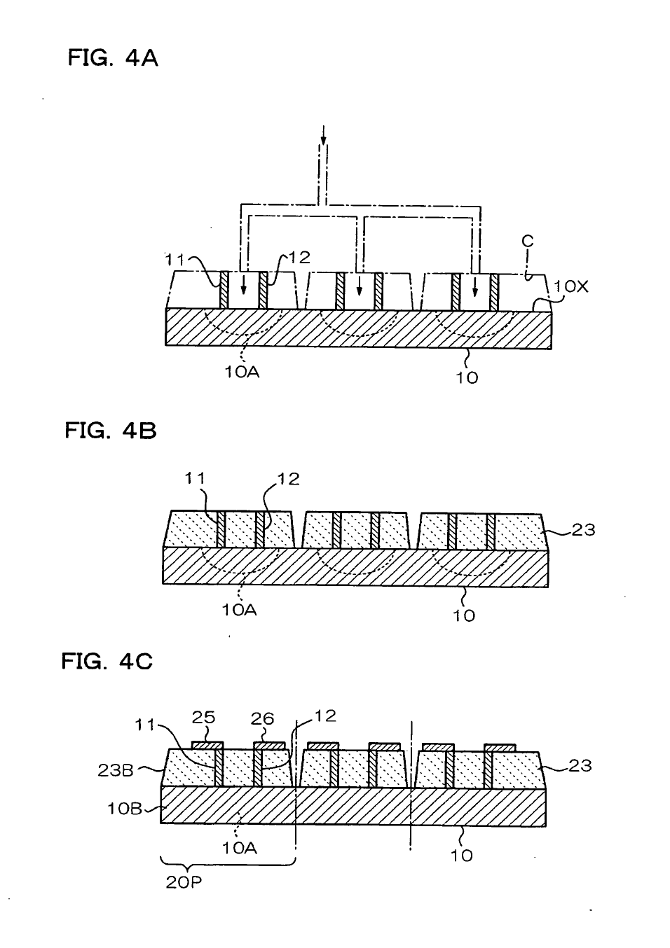

The third embodiment according to the present invention is described below with reference to FIGS. 4A to 4C. In this embodiment, constituent elements the same as the constituent elements in the first embodiment or the second embodiment are denoted by the same symbols. Description of these constituent elements is omitted.

In this embodiment, a thermoplastic resin layer is formed on the mounting surface 10X of the semiconductor substrate 10 by molding. In more detail, the semiconductor substrate 10 is placed in a die so that a cavity C is disposed on the mounting surface 10X of the semiconductor substrate 10 as indicated by one-dot lines shown in FIG. 4A, and a molten resin is injected into the cavity C as indicated by the arrow by using an injection molding machine (not shown) or the like. The injected resin is cured due to a decrease in the temperature inside the die, whereby a thermoplastic resin layer 23 shown in FIG. 4B is formed.

In this embodiment, since the thermoplastic resin layer 23 is formed by molding, the thermoplastic resin layer 23 can be formed into a desired shape corresponding to the shape of the die. In the example shown in the drawings, the thermoplastic resin layers 23 are independently formed in units of the integrated circuits 10A formed in the semiconductor substrate 10. In this embodiment, an integral thermoplastic resin layer may be formed in the same manner as in the first embodiment and the second embodiment. A plurality of separated thermoplastic resin layers as in this embodiment may be applied in the first embodiment and the second embodiment.

As shown in FIG. 4C, the conductors 25 and 26 electrically connected to the bump electrodes 11 and 12 are formed by using the same method as in the second embodiment. Then, electronic components 20P, each of which includes the electronic structure split substrate 10B, a thermoplastic split layer 23B, and the conductors 25 and 26, are formed in the same manner as in the first embodiment.

In this embodiment, since the thermoplastic resin layers 23 are separately formed in units of the integrated circuits 10A, the electronic components 20P can be formed merely by dividing the semiconductor substrate 10. Therefore, the dividing operation can be easily performed since the dividing operation can be completed merely by using the scribe and break method, for example.

In this embodiment, the conductive layer 14 used in the first embodiment may be disposed in the die so as to come in contact with the bump electrodes 11 and 12, and the thermoplastic resin layer 23 may be formed so as to be disposed between the semiconductor substrate 10 and the conductive layer 14 by injecting a resin into the die.

Fourth Embodiment

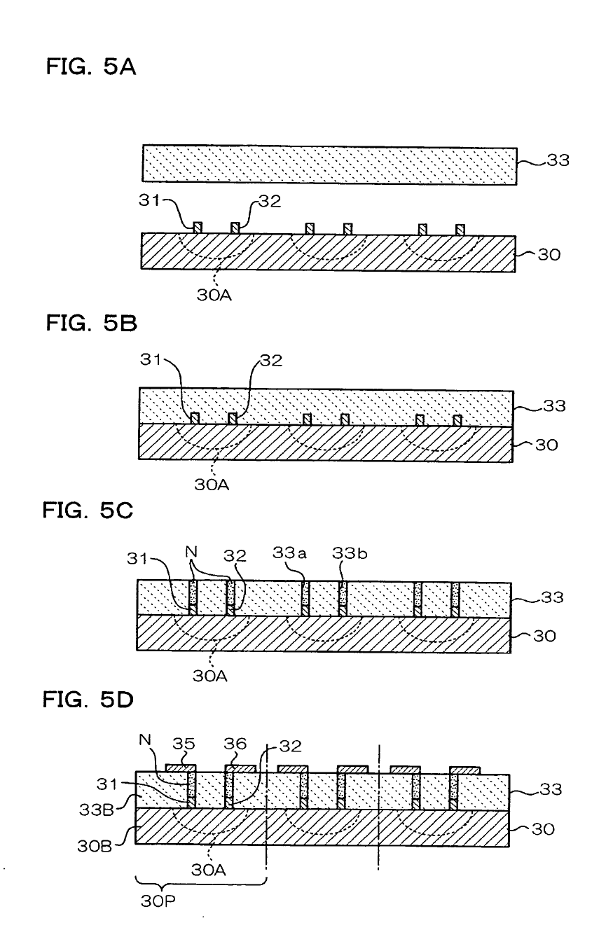

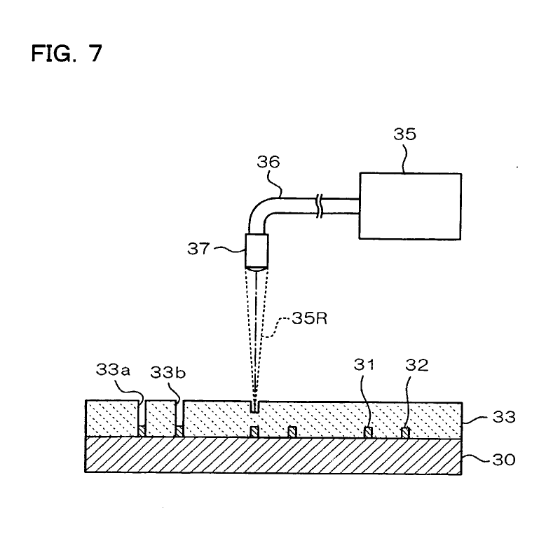

The fourth embodiment according to the present invention is described below with reference to FIGS. 5A to 5D and FIG. 7. In this embodiment, as shown in FIGS. 5A and 5B, when a thermoplastic resin layer 33 is formed on a semiconductor substrate 30 including a plurality of integrated circuits 30A provided with bump electrodes 31 and 32, the bump electrodes 31 and 32 are buried in the thermoplastic resin layer 33. However, the ends of the bump electrodes 31 and 32 are not exposed from the surface of the thermoplastic resin layer 33. Therefore, in this embodiment, the thermoplastic resin layer 33 may be formed to a thickness greater than the projection height of the bump electrodes 31 and 32 to a certain extent.

As shown in FIG. 5C, holes 33a and 33b are formed in the surface of the thermoplastic resin layer 33 to expose the ends of the bump electrodes 31 and 32. In this case, since the holes can be formed in the thermoplastic resin layer 33 after alignment based on the semiconductor substrate 30 which shows only a small amount of dimensional change due to a temperature change, the holes 33a and 33b can be formed at accurate positions. The thermoplastic resin layer 33 may be formed of a material which transmits light, and the holes may be formed based on the bump electrodes 31 and 32 seen from the surface.

FIG. 7 shows an example of the hole formation method in this embodiment. In this hole formation method, the thermoplastic resin is caused to melt and burn down by applying a laser beam 35R generated by a laser 35 to the thermoplastic resin layer 33 to form the holes 33a and 33b. In the example shown in FIG. 7, the laser beam 35R is applied to the thermoplastic resin layer 33 from the laser 35 through an optical fiber 36 and an optical system 37. The holes 33a and 33b are formed so that the ends of the bump electrodes 31 and 32 are exposed in the holes. The diameter of the holes 33a and 33b is about 10 to 50 μm, for example. The diameter of the holes 33a and 33b may be approximately the same as or smaller than the diameter of the bump electrodes 31 and 32.

After the holes 33a and 33b are formed as described above, the holes 33a and 33b are filled with a conductive material N as shown in FIG. 5C. As the conductive material N, a material obtained by melting powder of a low-melting-point metal such as Sn, IN, or Zn by heating, a columnar product of the above metal, a material obtained by curing a conductive fluid material in which conductive particles are dispersed such as a metal paste, or the like may be used. The bump electrodes 31 and 32 and the conductive material N may be bonded through an alloy junction by performing a heat treatment or the like. The conductive material N is partially exposed from the surface of the thermoplastic resin layer 33 in a state in which the conductive material N is electrically connected to the bump electrodes 31 and 32.

Conductive patterns 35 and 36 electrically connected to the conductive material N are formed on the surface of the thermoplastic resin layer 33 by using the same method as in the second embodiment or the third embodiment. Then, electronic components 30P, each of which includes an electronic structure split substrate 30B, a thermoplastic resin split layer 33B, and the conductive patterns 35 and 36, are formed by using the same method as in the first embodiment (see FIG. 5D).

In this embodiment, since it is unnecessary to expose the bump electrodes 31 and 32 from the surface of the thermoplastic resin layer 33 in the step of forming the thermoplastic resin layer, this step can be easily performed. Moreover, since the holes are formed in the thermoplastic resin layer 33 and are filled with the conductive material N electrically connected to the bump electrodes 31 and 32, electrical reliability between the bump electrodes 31 and 32 and the conductive patterns 35 and 36 can be increased.

The electronic component 30P formed by this embodiment is essentially the same as the electronic component in each embodiment described above. However, since electrical conduction between the bump electrodes 31 and 32 and the conductive patterns 35 and 36 is secured by using the conductive material N, the electronic component 30P has an advantage in that the electronic component 30P has higher degrees of freedom relating to the shape and projection height of the bump electrodes 31 and 32, the thickness of the thermoplastic resin layer 33, and the like.

Fifth Embodiment

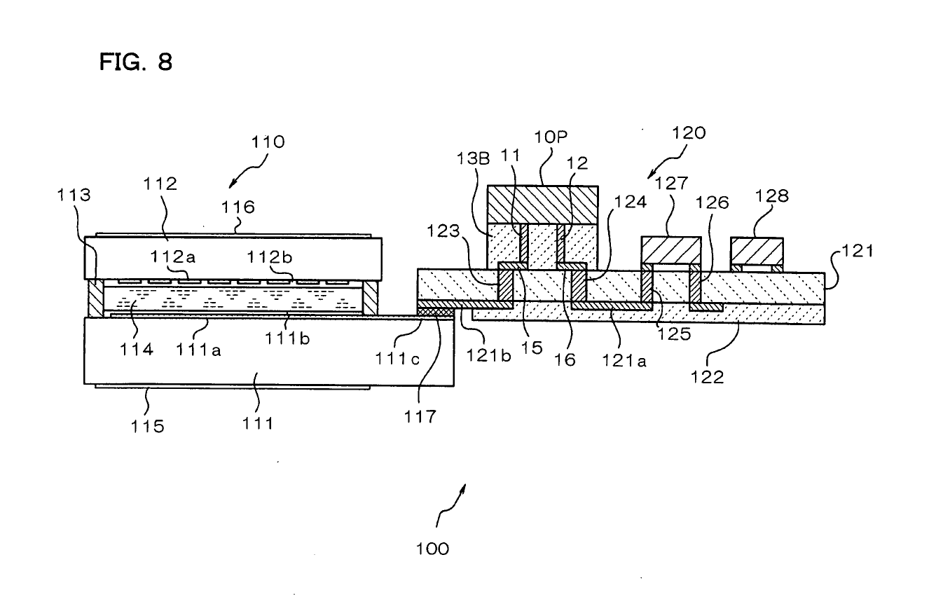

The fifth embodiment showing an electro-optical device according to the present invention is described below with reference to FIG. 8. In this embodiment, an electro-optical device 100 includes the electronic component 10P manufactured by the above-described embodiment. The following description is given taking the case of using the electronic component 10P as an example. However, the electronic component 10P′, 20P, or 30P may be used in the same manner as the electronic component 10P. The electronic component 10P may include a circuit which generates a drive signal for driving the electro-optical device in the integrated circuit (specifically, mounting unit of a liquid crystal drive IC chip).

The electro-optical device 100 in this embodiment is a liquid crystal display device, and includes an electro-optical panel 110 (liquid crystal panel) and a circuit board 120 (flexible interconnect substrate) mounted on the electro-optical panel 110. The electro-optical panel 110 is formed by attaching a pair of substrates 111 and 112 formed of glass, plastic, or the like using a sealing material 113. An electro-optical substance 114 such as a liquid crystal is sealed between the substrates 111 and 112. A transparent electrode 111a formed of a transparent conductor such as ITO is formed on the inner surface of the substrate 111, and an alignment film 111b covers the transparent electrode 111a. A transparent electrode 112a is formed of the same material as described above on the inner surface of the substrate 112, and an alignment film 112b covers the transparent electrode 112a. Polarizers 115 and 116 are respectively disposed on the outer surfaces of the substrates 111 and 112.

In the circuit board 120, an interconnect pattern 121a is formed of Cu or the like on the surface of an insulating substrate 121 (lower surface in FIG. 8). The insulating substrate 121 is formed of a thermosetting resin such as epoxy or polyimide, or a thermoplastic resin such as polyester, polyamide, aromatic polyester, aromatic polyamide, tetrafluoroethylene, or polyimide. The interconnect pattern 121a is covered with a protective film 122 excluding a terminal section such as a connection terminal section 121b connected with the electro-optical panel 110. The connection terminal section 121b is electrically connected to an interconnect 111c on the surface of the substrate 111 through an anisotropic conductive film 117. The interconnect 111c is electrically connected to the transparent electrodes 111a and 112a, and pulled toward a substrate overhang section of the substrate 111 (section overhanging outward from the external shape of the substrate 112).

The ends of connection pads 123, 124, 125, and 126 electrically connected to the interconnect pattern 121a are exposed from the surface (upper surface in FIG. 8) of the insulating substrate 121 opposite to the surface on which the interconnect pattern 121a is formed. Various electronic parts 127 and 128 are mounted on the connection pads. The electronic component 10P is mounted on the connection pads 123 and 124. The electronic component 10P is pressed against the circuit board 120 in a state in which the electronic component 10P is heated by using a pressure heating head or the like. This causes a part of the thermoplastic resin split layer 13B to soften or dissolve, and the thermoplastic resin split layer 13B covers the circumference of the conductive connection sections between the conductive patterns 35 and 36 and the connection pads 123 and 124, whereby the space between the electronic component 10P and the insulating substrate 121 is completely closed. This makes it unnecessary to perform an injection operation of an underfill resin, whereby the mounting operation is facilitated. Moreover, since occurrence of voids can be prevented, electrical reliability of the mounting structure can be increased.

In particular, in the case where the insulating substrate 121 of the circuit board in this embodiment is formed of a thermoplastic resin, since weldability with the thermoplastic resin split layer 13B of the electronic component 10P is high, a mounting structure provided with sufficient holding power and sealing performance can be obtained.

Sixth Embodiment

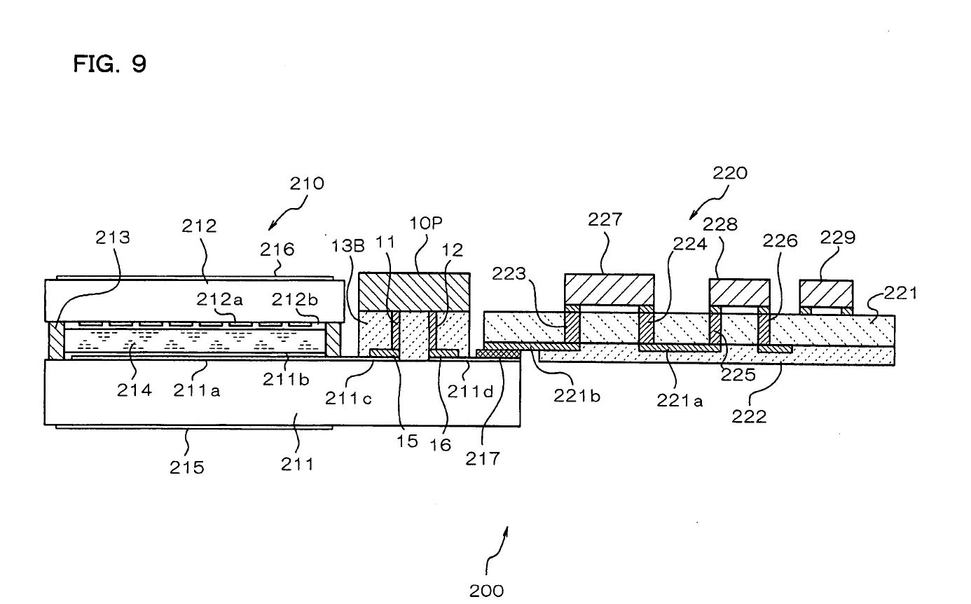

The sixth embodiment showing another electro-optical device according to the present invention is described below with reference to FIG. 9. An electro-optical device 200 in this embodiment includes an electro-optical panel 210 and a circuit board 220 mounted on the electro-optical panel 210. The electro-optical panel 210 has almost the same structure as that of the electro-optical panel 110 in the fifth embodiment. Substrate 211 and 212, transparent electrodes 211a and 212a, alignment films 211b and 212b, an interconnect 211c, a sealing material 213, an electro-optical substance 214 such as a liquid crystal, polarizers 215 and 216, and an anisotropic conductive film 217 are the same as those described in the fifth embodiment. Therefore, description of these constituent elements is omitted. In this embodiment, an input interconnect 211d to which the circuit board 220 is electrically connected is formed separately from the interconnect 211c.

In the circuit board 220, an insulating substrate 221, an interconnect pattern 221a, a connection terminal section 221b, a protective film 222, connection pads 223, 224, 225, and 226, and electronic parts 227, 228, and 229 are the same as those described in the fifth embodiment. Therefore, description of these constituent elements is omitted.

This embodiment differs from the fifth embodiment in that the electronic component 10P is directly mounted on the surface of the substrate 211 which makes up the electro-optical panel 210. The electronic component 10P is directly mounted on the substrate 211 in a state in which the conductive patterns 15 and 16 are electrically connected to the interconnect 211c pulled toward the substrate overhang section of the substrate 211 and the input interconnect 211d. The substrate 211 is formed of glass, plastic, or the like. In this embodiment, the thermoplastic resin split layer 13B softens or dissolves by disposing the electronic component 10P on the substrate 211 and applying pressure and heat to the electronic component 10P, whereby the electronic component 10P adheres to the substrate 211.

As described above, in this embodiment, since the electronic component 10P can be directly mounted on the substrate 211 of the electro-optical panel 210, it is unnecessary to use an anisotropic conductive film, whereby the mounting cost can be reduced, and the mounting operation can be efficiently performed.

Seventh Embodiment

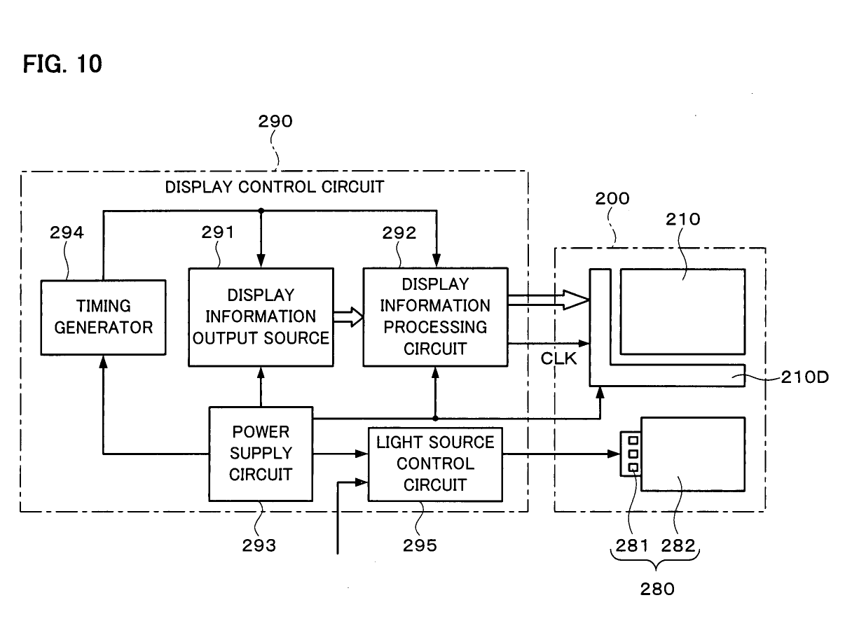

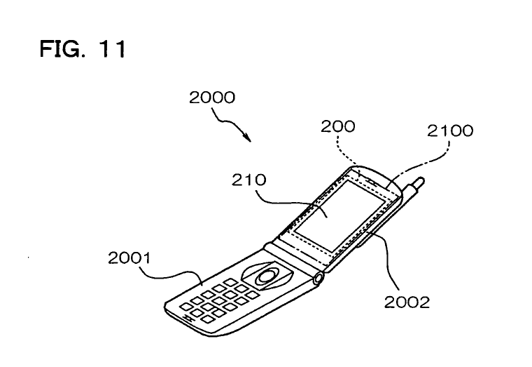

An embodiment of an electronic instrument according to the present invention is described below with reference to FIGS. 10 and 11. In this embodiment, an electronic instrument including the above-described electro-optical device (liquid crystal device 200) as display means is described below. FIG. 10 is a schematic configuration diagram showing the entire configuration of a control system (display control system) for the liquid crystal device 200 in the electronic instrument in this embodiment. The electronic instrument shown in FIG. 10 includes a display control circuit 290 which includes a display information output source 291, a display information processing circuit 292, a power supply circuit 293, a timing generator 294, and a light source control circuit 295. The liquid crystal device 200 includes a driver circuit 210D which drives the liquid crystal panel 210 having the above-described configuration. The driver circuit 210D is formed by a semiconductor IC chip of the electronic component 10P directly mounted on the liquid crystal panel 210 as described above. However, the driver circuit 210D may also be formed by a circuit pattern formed on the panel surface or a semiconductor IC chip or a circuit pattern mounted on a circuit board electrically connected to the liquid crystal panel.

The display information output source 291 includes a memory such as a read only memory (ROM) or a random access memory (RAM), a storage unit such as a magnetic recording disk or an optical recording disk, and a tuning circuit which tunes and outputs a digital image signal, and is formed to supply display information to the display information processing circuit 292 in the form of an image signal in a predetermined format or the like based on various clock signals generated by the timing generator 294.

The display information processing circuit 292 includes various conventional circuits such as a serial-parallel conversion circuit, an amplification/inversion circuit, a rotation circuit, a gamma correction circuit, and a clamping circuit. The display information processing circuit 292 performs processing of the input display information, and supplies the image information to the driver circuit 210D together with a clock signal CLK. The driver circuit 210D includes a scanning line driver circuit, a signal line driver circuit, and an inspection circuit. The power supply circuit 293 supplies a predetermined voltage to each constituent element.

The light source control circuit 295 supplies electric power supplied from the power supply circuit 293 to a light source section 281 (light emitting diode or the like in more detail) of the illumination device 280 based on a control signal input from the outside. The light source control circuit 295 controls ON/OFF of each light source of the light source section 281 corresponding to the control signal. The light source control circuit 295 can control the illuminance of each light source. Light emitted from the light source section 281 is applied to the liquid crystal panel 210 through a light guide plate 282.

FIG. 11 shows the appearance of a portable telephone which is an embodiment of the electronic instrument according to the present invention. An electronic instrument 2000 includes an operating section 2001 and a display section 2002. A circuit board 2100 is disposed inside the display section 2002. The liquid crystal device 200 is mounted on the circuit board 2100. The liquid crystal panel 210 can be seen through the surface of the display section 2002.

The present invention is not limited to the above-described examples shown in the drawings. Various modifications and variations can be made within the scope and spirit of the present invention. The above-described embodiment of the electro-optical device illustrates a passive matrix liquid crystal display device as an example. However, the present invention can be applied not only to the passive matrix liquid crystal display device shown in the drawings, but also to an active matrix liquid crystal display device (liquid crystal display device including a thin-film transistor (TFT) or thin-film diode (TFD) as a switching device, for example). Moreover, the present invention can also be applied to various electro-optical devices such as an electroluminescent device, an organic electroluminescent device, a plasma display device, an electrophoresis display device, and a device using an electron emission element (field emission display, surface-conduction electron-emitter display, and the like) in addition to the liquid crystal display device.

The present invention is not limited to the above-described embodiments, and various modifications can be made. For example, the present invention includes various other configurations substantially the same as the configurations described in the embodiments (in function, method and effect, or in objective and effect, for example). The present invention also includes a configuration in which an unsubstantial portion in the described embodiments is replaced. The present invention also includes a configuration having the same effects as the configurations described in the embodiments, or a configuration able to achieve the same objective. Further, the present invention includes a configuration in which a publicly known technique is added to the configurations in the embodiments.

1. A method of manufacturing an electronic component, comprising:
forming a thermoplastic resin layer on a surface of a semiconductor substrate including a plurality of integrated circuits and a bump electrode provided on each of the integrated circuits, to bury the bump electrode;
forming a conductive pattern on a surface of the thermoplastic resin layer opposite to the semiconductor substrate, and electrically connecting the conductive pattern to the bump electrode; and
dividing the semiconductor substrate in units of the integrated circuits.

2. The method of manufacturing an electronic component as defined in claim 1,
wherein the thermoplastic resin layer is formed while heating the semiconductor substrate or the thermoplastic resin layer.

3. The method of manufacturing an electronic component as defined in claim 1,
wherein the thermoplastic resin layer is formed on the semiconductor substrate by molding.

4. The method of manufacturing an electronic component as defined in claim 1,
wherein the thermoplastic resin layer is formed so that part of the bump electrode is exposed from the surface of the thermoplastic resin layer.

5. The method of manufacturing an electronic component as defined in claim 1, wherein:
the thermoplastic resin layer is formed so that the bump electrode is electrically connected to conductive material previously disposed on the side opposite to the semiconductor substrate; and
the conductive pattern is formed by patterning the conductor material.

6. The method of manufacturing an electronic component as defined in claim 1, further comprising:
forming a hole to expose part of the bump electrode on a surface of the thermoplastic resin layer opposite to the semiconductor substrate and filling the hole with conductive material, between the steps of forming the thermoplastic resin layer and the conductive pattern.

7. The method of manufacturing an electronic component as defined in claim 1,
wherein the conductive pattern is formed by applying a fluid material on a surface of the thermoplastic resin layer opposite to the semiconductor substrate and curing the fluid material.

8. The method of manufacturing an electronic component as defined in claim 7,
wherein the fluid material is applied by ejecting the fluid material in the form of drops.

9. The method of manufacturing an electronic component as defined in claim 7,
wherein the fluid material is applied by printing the fluid material in the form of paste.

10. The method of manufacturing an electronic component as defined in claim 1, wherein:
the step of forming the conductive pattern includes forming a resist layer having a patterned opening on a surface of the thermoplastic resin layer opposite to the semiconductor substrate; and
the conductive pattern is formed in the opening in the resist layer.

11. The method of manufacturing an electronic component as defined in claim 10, wherein:
the step of forming the conductive pattern includes a step of ejecting a solvent containing conductive fine particles; and
the resist layer is formed so that an upper surface of the resist layer has a lower affinity to the solvent in comparison with the surface of the thermoplastic resin layer opposite to the semiconductor substrate.

12. The method of manufacturing an electronic component as defined in claim 10, further comprising:
removing the resist layer after the step of forming the conductive pattern.

13. A method of manufacturing an electro-optical device, comprising:
mounting an electronic component manufactured by the method as defined in claim 1 on a circuit board by thermocompression bonding; and
mounting the circuit board on an electro-optical panel.

14. A method of manufacturing an electro-optical device, comprising:
mounting an electronic component manufactured by the method as defined in claim 1 on a substrate of an electro-optical panel by thermocompression bonding.

15. An electronic component comprising:
a semiconductor substrate including a bump electrode;
a thermoplastic resin layer formed on a surface of the semiconductor substrate on which the bump electrode is formed; and
a conductive pattern formed on a surface of the thermoplastic resin layer and electrically connected to the bump electrode,
wherein an outer edge of the thermoplastic resin layer is disposed on or inside an outer edge of the semiconductor substrate.

16. An electro-optical device comprising:
an electro-optical panel; and
a circuit board mounted on the electro-optical panel,
wherein the electronic component as defined in claim 15 is mounted on the circuit board.

17. An electro-optical device comprising:
an electro-optical panel; and
the electronic component as defined in claim 15 mounted on a substrate of the electro-optical panel.

18. An electro-optical device comprising:
the electro-optical device as defined in claim 16; and
control means for the electro-optical device.

19. An electro-optical device comprising:
the electro-optical device as defined in claim 17; and
control means for the electro-optical device.
